(19) United States
(12) Patent Application Publication
(10) Pub. No.: US 2015/0230335 A1
(43) Pub. Date: Aug. 13, 2015

(54) COPPER CLAD LAMINATE AND METHOD FOR MANUFACTURING THE SAME

(71) Applicant: SAMSUNG ELECTRO-MECHANICS CO., LTD., Gyeonggi-Do (KR)

(72) Inventors: Kwang Jik LEE, Sungnam-si (KR); Jin Gu KIM, Suwon-si (KR); Myung Jae YOO, Ulsan-si (KR); Ichiro OGURA, Suwon-si (KR); Hye Suk SHIN, Hwasung-si (KR)

(73) Assignee: SAMSUNG ELECTRO-MECHANICS CO., LTD., Gyeonggi-Do (KR)

(21) Appl. No.: 14/618,681

(22) Filed: Feb. 10, 2015

(30) Foreign Application Priority Data
Feb. 10, 2014 (KR) 10-2014-0014906

(51) Int. Cl. H05K 1/05; H05K 3/38; H05K 1/03

(52) U.S. Cl. CPC H05K 1/056; H05K 1/0373; H05K 3/381; H05K 3/384; H05K 3/382

(57) ABSTRACT

Embodiments of the invention provide a copper clad laminate, and more particularly, to a copper clad laminate and a method for manufacturing the same capable of increasing a peel strength by adding a stress relaxation filler to an insulating layer of a copper clad laminate, along with an inorganic filler. To improve an adhesion of a substrate, the stress relaxation filler is distributed into the resin, along with the inorganic filler, and is entirely distributed into the varnish, and is more effectively added to the vicinity of a bonded interface between the insulating layer and the copper clad layer, thereby improving the overall adhesion.

### CROSS REFERENCE TO RELATED APPLICATION

This application claims the benefit of and priority under 35 U.S.C. §119 to Korean Patent Application No. KR 10-2014-0014906, entitled, “COPPER CLAD LAMINATE AND METHOD FOR MANUFACTURING THE SAME,” filed on Feb. 10, 2014, which is hereby incorporated by reference in its entirety into this application.

### BACKGROUND

1. Field of the Invention

The present invention relates to a copper clad laminate, and more particularly, to a copper clad laminate and a method for manufacturing the same capable of increasing a peel strength by adding a stress relaxation filler to an insulating layer of a copper clad laminate, along with an inorganic filler.

2. Description of the Related Art

Recently, with the tendency of integration and miniaturization of electronic devices including digital equipment, effectively radiating heat generated inside the electronic devices becomes an important issue. Since a larger amount of energy is consumed as heat within the miniaturized and integrated electronic devices and thus a heat density is increased, when heat is not sufficiently radiated, the heat deteriorates electronic parts, thereby causing problems such as malfunction and shortening of lifespan.

As a method for solving the problems, a method for forcibly radiating heat inside the equipment using a fan and a method for radiating heat by attaching a heat sink to a heat source, for example, have been typically used. As another method, heat radiating characteristics are improved by dispersing the inorganic filler having high heat conductivity into resin, but a bonded surface between the inorganic filler and an interface of resin is separated and thus an adhesion between the insulating layer and a copper clad layer may be reduced. Thus, the heat radiating characteristics are improved due to the high heat conductivity, but the adhesion may be reduced.

The adhesion is one of the important characteristics of the substrate, and therefore to solve the problem of reduction in the adhesion, a method for improving an adhesion by increasing a bonded area between an insulating layer and a copper clad layer by forming roughness on a surface of a copper thin film or a method for improving an adhesion by controlling physical characteristics of resin by adding an inorganic filler of which the surface is treated with a silane coupling agent to the resin has been used, for example, as described in Japanese Patent Publication No. 2009-152501. However, even though various efforts to improve the adhesion have been conducted, there is a limitation in that the adhesion may not be largely improved due to a stress which is generated by a difference in a coefficient of thermal expansion (CTE) between the resin and the copper thin film.

### SUMMARY

Accordingly, embodiments of the invention have been made to improve an adhesion by dispersing a stress relaxation filter into a resin, along with an inorganic filler.

Other embodiments of the invention improve an overall adhesion by entirely dispersing a stress relaxation filter into a varnish and more effectively adding the stress relaxation filler in the vicinity of a bonded interface between an insulating layer and a copper clad layer.

According to at least one embodiment of the invention, there is provided a copper clad laminate in which a copper clad is stacked on one surface or both surfaces of an insulating layer, wherein the insulating layer includes an inorganic filler and a stress relaxation filler.

According to at least one embodiment, the stress relaxation filler is an elastic material.

According to at least one embodiment, the stress relaxation filler is added at 20 part per hundred resin with respect to a resin forming the insulating layer.

According to at least one embodiment, the stress relaxation filler is added into the resin forming the insulating layer at 0.05 wt % or more to 10 wt % or less with respect to the existing inorganic filler.

According to at least one embodiment, the stress relaxation filler is included in the vicinity of a bonded interface between the insulating layer and the copper clad layer.

According to at least one embodiment, the stress relaxation filler is distributed in a region adjacent to the bonded interface between the insulating layer and the copper clad layer and is distributed in a thickness region of about 20% with respect to the overall thickness of the insulating layer at the bonded interface between the insulating layer and the copper layer.

According to at least another embodiment of the invention, there is provided a method for manufacturing a copper clad laminate, including preparing a first varnish, a second varnish including a stress relaxation filler, an inorganic reinforcement material, and a copper clad, impregnating the first varnish into the inorganic reinforcement material to produce an insulating film, injecting a second varnish including the stress relaxation filler onto the insulating film, drying the insulating film onto which the second varnish is injected to produce a prepreg (PPG), forming roughness on the copper clad, and pressing the copper clad to the prepreg.

According to at least another embodiment of the invention, there is provided a method for manufacturing a copper clad laminate, including preparing a first varnish, a second varnish including a stress relaxation filler, an inorganic reinforcement material, and a copper clad; impregnating the first varnish into the inorganic reinforcement material to produce an insulating film, injecting a second varnish including the stress relaxation filler onto the insulating film, drying the insulating film onto which the second varnish is injected to produce a prepreg (PPG), forming roughness on a surface of the prepreg, performing electroless plating on the prepreg formed with the roughness, and performing electroplating on the electroless-plated prepreg.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1A is an SEM photograph of an interface of a general copper clad laminate.

FIG. 1B is a separated cross-sectional view of a vicinity of an interface of the general copper clad laminate.

FIG. 2 is a cross-sectional view of a copper clad laminate according to at least one embodiment of the invention.

FIG. 3A is a graph of a peel strength of the copper clad laminate according to at least one embodiment of the invention.

FIG. 3B is a graph of a peel strength of a general copper clad laminate.

FIG. 4 is a process flow chart of a method for manufacturing a copper clad laminate according to at least one embodiment of the invention.

FIG. 5 is a process flow chart of another example of a method for manufacturing a copper clad laminate according to at least one embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Structure of Copper Clad Laminate

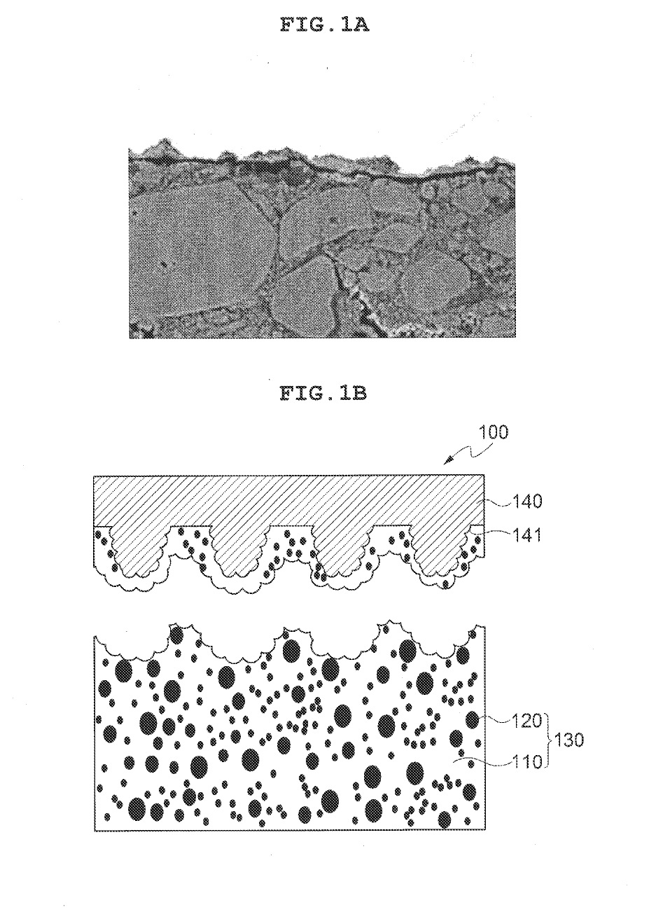

FIG. 1A is an SEM photograph of an interface of a general copper clad laminate and FIG. 1B is a separated cross-sectional view of a vicinity of an interface of the general copper clad laminate.

It may be confirmed from FIGS. 1A and 1B that a separation of an insulating layer 130 from a copper clad layer 140 is not made at an accurate interface 141 between the insulating layer and the copper clad layer, but a resin 110 including an inorganic filler 120 is attached to and then separated from the copper clad layer 140 in the vicinity of a bonded interface between the insulating layer and the copper clad layer. Seeing with the naked eye, it looks like that the insulating layer and the copper clad layer are clearly separated from the interface 141, but seeing from a V-SEM photograph, it may be substantially confirmed that the insulating layer 130 is attached to the copper clad layer 140 and then separated therefrom. That is, it may be appreciated that a breakage may occur due to a stress which is generated by a difference in a coefficient of thermal expansion (CTE) between resin and copper rather than due to an interface separation 141.

The inorganic filler 120 may be added into the resin to improve moldability of the resin 110 and physical properties such as insulating characteristics, mechanical rigidity, and coefficient of thermal expansion thereof. An example of the inorganic filler may include silica (SiO₂), alumina (Al₂O₃), zinc oxide (ZnO), calcium oxide (CaO), magnesium oxide (MgO), and zirconia (ZrO₂), as non-limiting examples, but is not particularly limited thereto, and therefore among those, alumina (Al₂O₃) or silica (SiO₂) having a low coefficient of thermal expansion may be mainly used.

A content of the inorganic filler may be changed depending on physical properties such as moldability, low stress ability, and high temperature strength, but when the overall varnish other than a solvent is 100 volume %, the inorganic filler preferably is 20 volume % or more to 60 volume % or less, more preferably, 30 volume % or more to 55 volume % or less. When the content of the inorganic filler is within the above range, the resin may have the low coefficient of thermal expansion while the moldability of the resin is kept well. As the content of the inorganic filler is increased, the coefficient of thermal expansion (CTE) of the resin is linearly reduced, but may not be reduced indefinitely due to the process of manufacturing a substrate.

When a large amount of inorganic filler is added into the resin, the dispersibility of the inorganic filler within a matrix is greatly reduced and thus the aggregation of the filler may occur and the viscosity of the resin is suddenly increased, such that it is difficult to form a product. Further, the bonded surface between the inorganic filler 120 and an interface of the resin 110 is separated and thus the stress agglomeration occurs, such that the adhesion between the insulating lay and the copper clad layer 140 may be reduced.

To solve the problem, the inorganic filler of which the surface is treated with a silane coupling agent, for example, may be used. Thus, one side of a molecule of the silane coupling agent is coupled with the inorganic filler and the other side thereof has affinity with the resin and thus the inorganic filler may be chemically coupled with the resin. Consequently, the bondability between the inorganic filler 120 and the interface of the resin 110 is good and thus the stress agglomeration is reduced, such that the adhesion between the insulating layer 130 and the copper clad layer 140 may be improved.

However, the coefficient of thermal expansion (CTE) of the epoxy resin 110 is about 70 to 100 ppm/° C. and the coefficient of thermal expansion is more increased at a glass transition temperature (Tg, 150 to 200° C.) or more and thus the coefficient of thermal expansion at high temperature reaches 150 to 180 ppm/° C. This coefficient of thermal expansion is much higher than that of the copper 140 which is 10 to 20 ppm/° C. and therefore there is a limitation in improving the adhesion between the insulating layer 130 and the copper clad layer 140 only by the surface treatment of the inorganic filler 120. That is, the resin 110 is thermally expanded in the copper thin film 140 formed with roughness due to the large difference in the coefficient of thermal expansion between the resin and the copper, such that a breakage may occur in the vicinity of the interface due to the stress.

To solve the above problem, various embodiments of the invention improve the adhesion between the insulating layer 130 and the copper clad layer 140 by adding a stress relaxation filler in addition to the inorganic filler 120 into the resin 110. The stress relaxation filler is an elastic material, and therefore when the volume of the resin having the large coefficient of thermal expansion is expanded due to the heat treatment process in the manufacturing process, relaxes the stress due to the volume expansion of the resin by a mechanism providing a space in which the volume of the resin is expanded while the volume thereof is reduced due to the characteristics of the stress relaxation filler having elasticity. Therefore, the stress between the inorganic filler and the interface of the resin to which the stress is intensively applied at the time of the heat treatment is reduced and the breakage due to the stress in the vicinity of the bonded interface between the insulating layer and the copper clad layer is prevented.

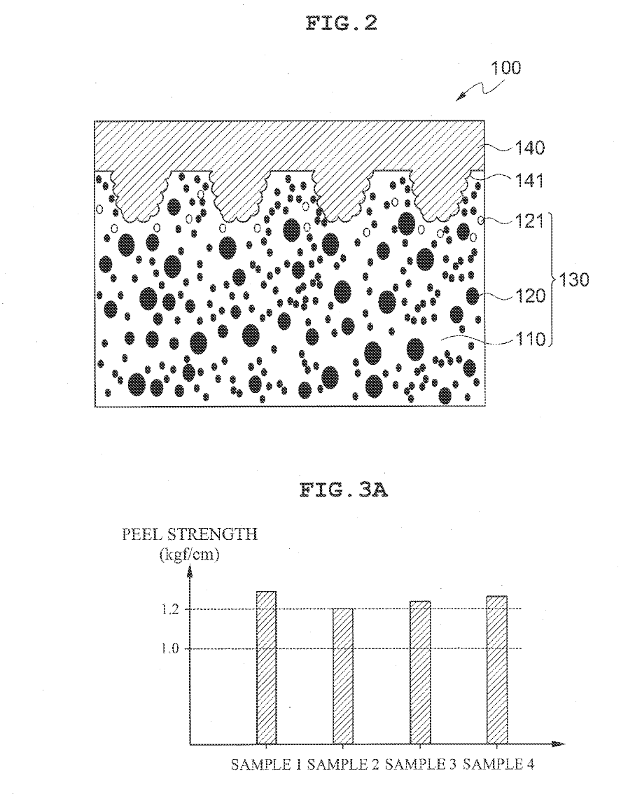

FIG. 2 is a cross-sectional view of a copper clad laminate according to at least one embodiment of the invention.

As illustrated in FIG. 2, in the cooper clad laminate 100 according to at least one embodiment of the invention, the inorganic filler 120 is added into the resin 110 forming the insulating layer 130 and the stress relaxation filler 121 is added to the vicinity of the bonded interface between the insulating layer 130 and the copper clad layer 140. Further, even though the stress relaxation filler is entirely distributed into the insulating layer, the interface breakage is reduced due to the stress due to the thermal expansion of the resin, but as illustrated in FIGS. 1A and 1B, since the separation of the insulating layer 130 from the copper layer 140 is not made at the accurate interface 141 between the insulating layer and the copper clad layer, but is made at the vicinity of the bonded interface between the insulating layer and the copper layer, the stress relaxation filler 121 is added only to the vicinity of the bonded interface between the insulating layer and the copper layer without needing to entirely disperse the stress relaxation filler 120 into the resin 110, thereby obtaining the above effect.

When the stress relaxation filler is entirely dispersed into the resin, a larger amount of dispersing agent and a complicated dispersion process are further required and the entire characteristics of the resin is reduced by changing the physical properties of the existing epoxy matrix. Further, since the role of the stress relaxation filler completely ends in the vicinity of the bonded interface between the insulating layer and the copper clad layer, a larger effect is not exhibited even though a larger amount of filler is dispersed into the overall resin.

Consequently, the stress relaxation filler 121 is added within about 20% of a thickness of the overall insulating layer from the bonded interface 141 between the insulating layer 130 and the copper clad layer 140 and thus the complicated filler dispersing process is omitted, such that the production process is simplified and the price competitiveness is increased. Further, since the stress relaxation filler is present only in the vicinity of the bonded interface between the insulating layer and the copper clad layer, the change in the existing epoxy matrix is minimized and at the same time the adhesion (peel strength) between the insulating layer 130 and the copper clad layer 140 is increased.

Meanwhile, the stress relaxation filler 121 is an elastic material and when the stress relaxation filler 121 is added into the resin 110, the volume of the stress relaxation filler 121 is reduced while absorbing the stress of the resin and thus the stress relaxation filler 121 serves to form the space in which the resin may be expanded. The size of the stress relaxation filler ranges from nm (nanometer) to a maximum of several μm (micrometer) and the stress relaxation filler is added at about 10% as compared with the existing inorganic filler 120 and may be added at 20 part per hundred resin (PHR) with respect to the resin 110. Thus, when a sum of the resin and the hardener is set to be 100, the use of the stress relaxation filler is about 20.

According to at least one embodiment, a minimum content of the stress relaxation filler is about 0.05 wt % as compared with the existing inorganic filler and when the minimum content is smaller than above 0.05 wt %, the stress relaxation effect is not substantially exhibited and when the minimum content thereof exceeds the above 10 wt %, the ratio of the inorganic filler to the overall filler amount is reduced and thus the heat conductivity characteristics and the thermal expansion characteristics of the copper clad laminate may be reduced. For example, when the film for improving the heat conductivity is made, a large amount of alumina (Al₂O₃) filler having good heat conductivity is added into the resin so as to meet the purpose and when a larger amount of stress relaxation filler is added, the amount of alumina filler is reduced as much and thus the heat conductivity characteristics and the thermal expansion characteristics is reduced.

Therefore, when the stress relaxation filler is added at 0.05 wt % or more to 10 wt % as compared with the existing inorganic filler and is added at about 20% of the overall thickness of the insulating layer from the bonded interface between the insulating layer and the copper clad layer, thereby effectively achieving the objectives of the invention.

Consequently, when the stress relaxation filler 121 is dispersed into the place where the insulating layer 130 and the copper clad layer 140 are broken under the above condition, the stress relaxation filler itself has the reduced volume while absorbing the stress of the resin, thereby forming the space in which the resin is expanded. Thus, the stress relaxation filler reduces the stress at the vicinity of the bonded interface between the insulating layer and the copper clad layer and prevents the breakage at the vicinity of the interface, such that the adhesion (peel strength) is improved.

Method for Manufacturing Copper Clad Laminate

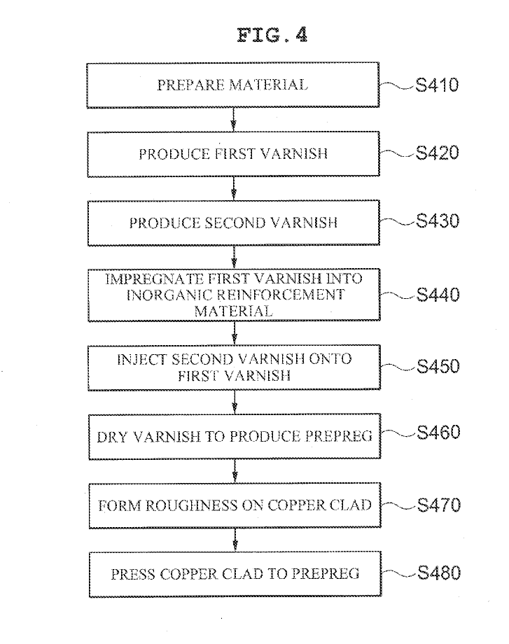

FIG. 4 is a process diagram sequentially illustrating a method for manufacturing a copper clad laminate according to at least one embodiment of the invention.

As illustrated in FIG. 4, the method for manufacturing a copper clad laminate according to at least one embodiment of the invention is formed of a total of eight steps. Thus, the method for manufacturing a copper clad laminate includes preparing a material for producing a varnish (S410), producing a first varnish (S420), producing a second varnish (S430), impregnating the first varnish into an inorganic reinforcement material (S440), injecting the second varnish onto the first varnish (S450), drying the varnish in a drier to produce a prepreg (S460), forming roughness on the prepared copper clad (S470), and pressing the copper clad on the prepreg (S480).

According at least one embodiment, as the material (S410) for producing the varnish, the resin, the inorganic filler, and the stress relaxation filler is used. As the resin, both of a thermoplastic resin and a thermosetting resin are used, and in more detail, an aromatic polysulfone resin, a polyamideimide resin, an epoxy resin, a phenol resin, for example, are used, but the resin is not particularly limited thereto. Among those, the epoxy resin having good moldability or electrical insulation is mainly used and when the epoxy resin as the thermosetting resin is used, a hardener or a hardening accelerator of the epoxy resin is used if necessary.

According to at least one embodiment, a content of the hardener is not particularly limited, but may range from about 10 to 60 parts by weight based on 100 parts by weight of the overall resin composition other than the hardening accelerator and the inorganic filler, preferably, about 20 to 50 parts by weight. When the content of the hardener is in the above range, the strength and the heat resistance of the hardening product are exhibited well and the moldability thereof is exhibited well due to fluidability.

According to at least one embodiment, the hardening accelerator ranges from about 0.01 to 10 parts by weight with respect to 100 parts by weight of the overall resin composition, preferably, about 0.01 to 0.5 parts by weight. When the content of the hardening accelerator is in the above-mentioned range, the hardening of the resin composition is made at a low temperature within a short period of time and the maintenance safety of the resin composition may be kept well.

According to at least one embodiment, the inorganic filler is added into the resin to improve moldability of the resin and physical properties, such as insulating characteristics, mechanical rigidity, and coefficient of thermal expansion thereof. In the case of the resin, when the hardness is increased, the resin has fragile characteristics and has a portion which is vulnerable to thermal stability and dimension stability and an interfacial peel phenomenon occurs due to the change in volume of the polymer or the difference in the coefficient of thermal expansion between the polymer and the substrate at the time of bonding the micro-electronic material, such that the connection defect occurs. To solve the problem, when the inorganic filler is added into the resin, the moldability of the resin is improved and the composite material having the high mechanical physical properties and the heat resistance characteristics are obtained.

Meanwhile, according to at least one embodiment of the invention, the stress relaxation filler in addition to the inorganic filler is added into the resin to improve the adhesion between the insulating layer and the copper clad layer.

When the material (e.g., resin, inorganic filler, and stress relaxation filler, as non-limiting examples) for producing a varnish is prepared, the first varnish is produced (S420). The first varnish is a general varnish and means the varnish, which does not include the stress relaxation filler according to at least one embodiment of the invention. Generally, the varnish is produced by melting the resin in a solvent and for the effective reaction, additives such as a catalyst, a drying agent, and an antifoaming agent are used together. As the solvent, to melt the resin, a polar organic solvent, such as toluene and xylene, is mainly used and according to at least one embodiment, methyl ethyl ketone (MEK) is used.

When the first varnish is produced, the stress relaxation filler according to at least one embodiment of the invention produces the dispersed second varnish (S430). The viscosity of the second varnish is controlled by controlling the amount of solvent (MEK) and the amount of added stress relaxation filler is 0.05 wt % or more to 10 wt % or less as compared with the inorganic filler.

Next, the first varnish is impregnated into the inorganic reinforcement material such as paper, glass fiber, and glass non-woven fabric (S440) to produce the insulating film. According to at least one embodiment, the state in which the varnish is impregnated into the inorganic reinforcement material is defined as the insulating film, which is the same even in the following description. The inorganic reinforcement material improves physical properties, such as mechanical strength of the varnish and helps overcome the difference in coefficient of thermal expansion between resin and copper. When a proper amount of first varnish solution is poured into an impregnating bath and then the inorganic reinforcement material is impregnated into the varnish of the impregnating bath, the longitudinal and horizontal strength of the resin is increased and the dimension change due to the temperature is also reduced.

In other words, the resin has excellent insulating characteristics, but has drawbacks such as insufficient mechanical strength and the dimension change (i.e., coefficient of thermal expansion) due to the temperature about 10 times higher than that of metal. Therefore, to supplement the drawbacks, paper and glass fiber, for example, is used as the reinforcement material. In addition to this, a liquid crystal polymer (LCP) fiber reinforcement material, a carbon fiber reinforcement material, a quartz fiber reinforcement material and a glass sheet, for example, is used but the reinforcement material is not limited thereto.

As described above, the second varnish in which the stress relaxation filler is dispersed is injected onto one surface or both surfaces of the insulating film in which the first varnish is impregnated into the inorganic reinforcement material (S450). In this case, when the second varnish is injected onto the surface of the insulating film on which the copper clad layer is stacked and the copper clad layer is stacked on both surfaces of the insulating film, the second varnish is injected onto both surfaces of the insulating film. As the injection method of the second varnish, a spray method is used.

Next, the attached amount is controlled by controlling the thickness of the varnish of the insulating film using a squeeze roll and then is dried in a drier at a temperature of about 80 to 200° C. to produce a prepreg (S460). Further, the roughness is formed on the prepared copper clad (S470) and as a method for forming roughness, there is a chemical polishing method using etching and a mechanical polishing method for forming roughness by using a brush or injecting a nozzle. In this case, when the roughness of about 0.5 to 1.5 μm is formed, the adhesion between the insulating layer and the copper clad layer is improved and thus the peel strength of the substrate is increased.

Finally, when the copper clad formed with the roughness is pressed to the prepreg (S480), the resin of the prepreg is penetrated into the surfaces formed with the roughness of the copper clad due to the applied heat and pressure and then hardened. As the result, the copper clad laminate is obtained by dispersing the stress relaxation filler to the vicinity of the bonded interface between the insulating layer and the copper layer by the above process.

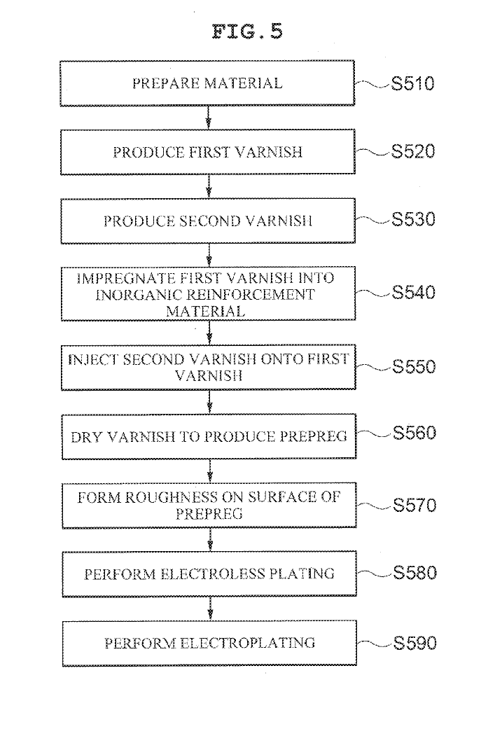

The method for manufacturing a copper clad laminate according to at least another embodiment of the invention will be described with reference to FIG. 5.

FIG. 5 is a process diagram sequentially illustrating a method for manufacturing a copper clad laminate according to at least another embodiment of the invention.

As illustrated in FIG. 5, the method for manufacturing a copper clad laminate according to at least another embodiment of the invention is formed of a total of nine steps. That is, the method for manufacturing a copper clad laminate may include preparing a material for producing a varnish (S510), producing a first varnish (S520), producing a second varnish (S530), impregnating the first varnish into an inorganic reinforcement material (S540), injecting the second varnish onto the first varnish (S550), drying the varnish in a drier to produce a prepreg (S560), forming roughness on the surface of the prepreg (S570), performing electroless plating on the prepreg formed with the roughness (S580), and performing electroplating (S590).

As the material for producing the varnish (S510), similar to at least one embodiment described above, the resin, the inorganic filler, and the stress relaxation filler are used. As the resin, both of a thermoplastic resin and a thermosetting resin are used, and in more detail, an aromatic polysulfone resin, a polyamideimide resin, an epoxy resin, and a phenol resin, for example, is used, but the resin is not particularly limited thereto. Among those, the epoxy resin having good moldability or electrical insulation is mainly used and when the epoxy resin as the thermosetting resin is used, a hardener or a hardening accelerator of the epoxy resin is used if necessary.

According to at least one embodiment, the inorganic filler is added into the resin to improve moldability of the resin and physical properties, such as insulating characteristics, mechanical rigidity, and coefficient of thermal expansion thereof. In the case of the resin, when the hardness is increased, the resin has fragile characteristics and has a portion which is vulnerable to thermal stability and dimension stability and an interfacial peel phenomenon occurs due to the change in volume of the polymer or the difference in the coefficient of thermal expansion between the polymer and the substrate at the time of bonding the micro-electronic material, such that the connection defect occurs. To solve the problem, when the inorganic filler is added into the resin, the moldability of the resin is improved and the composite material having the high mechanical physical properties and the heat resistance characteristics is obtained.

Meanwhile, according to at least one embodiment of the invention, the stress relaxation filler in addition to the inorganic filler is added into the resin to improve the adhesion between the insulating layer and the copper clad layer.

When the material (e.g., resin, inorganic filler, and stress relaxation filler, as non-limiting examples) for producing a varnish is prepared, the first varnish is produced (S520). The first varnish is a general varnish and means the varnish, which does not include the stress relaxation filler according to at least one embodiment of the invention. Generally, the varnish is produced by melting the resin in a solvent and for the effective reaction, additives such as a catalyst, a drying agent, and an antifoaming agent are used together. As the solvent, to melt the resin, a polar organic solvent, such as toluene and xylene, is mainly used and according to at least one embodiment of the invention, methyl ethyl ketone (MEK) is used.

When the first varnish is produced, the stress relaxation filler according to at least one embodiment of the invention produces the dispersed second varnish (S530). The viscosity of the second varnish is controlled by controlling the amount of solvent (MEK) and the amount of added stress relaxation filler is 0.05 wt % or more to 10 wt % or less as compared with the inorganic filler.

Next, the first varnish is impregnated into the inorganic reinforcement material such as paper, glass fiber, and glass non-woven fabric (S540) to produce the insulating film. According to at least one embodiment of the invention, the state in which the varnish is impregnated into the inorganic reinforcement material is defined as the insulating film, which is the same even in the following description. The inorganic reinforcement material improves physical properties, such as mechanical strength of the varnish and helps overcome the difference in coefficient of thermal expansion between resin and copper. When a proper amount of first varnish solution is poured into an impregnating bath and then the inorganic reinforcement material is impregnated into the varnish of the impregnating bath, the longitudinal and horizontal strength of the resin is increased and the dimension change due to the temperature are also reduced.

In other words, the resin has excellent insulating characteristics, but has drawbacks such as insufficient mechanical strength and the dimension change (i.e., coefficient of thermal expansion) due to the temperature about 10 times as large as metal. Therefore, to supplement the drawbacks, paper, and glass fiber, for example, is used as the reinforcement material. In addition to this, a liquid crystal polymer (LCP) fiber reinforcement material, a carbon fiber reinforcement material, a quartz fiber reinforcement material, and a glass sheet, for example, is used but the reinforcement material is not limited thereto.

As described above, the second varnish in which the stress relaxation filler is dispersed is injected onto one surface or both surfaces of the insulating film in which the first varnish is impregnated into the inorganic reinforcement material (S550). In this case, when the second varnish is injected onto the surface of the insulating film on which the copper clad layer is stacked and the copper clad layer is stacked on both surfaces of the insulating film, the second varnish is injected onto both surfaces of the insulating film. As the injection method of the second varnish, a spray method is used.

Next, the attached amount is controlled by controlling the thickness of the varnish of the insulating film using a squeeze roll and then is dried in a drier at a temperature of about 80 to 200° C. to produce a prepreg (S560). Further, the roughness is formed on the surface of the prepreg (S570) and as a method for forming roughness, there is a chemical polishing method using etching and a mechanical polishing method for forming roughness by using a brush or injecting a nozzle. In this case, when the roughness of about 0.5 to 1.5 μm is formed, the adhesion between the insulating layer and the copper clad layer is improved and thus the peel strength of the substrate is increased.

Finally, the copper clad is formed by performing the electroless plating (S580) and the electroplating (S590) on the prepreg formed with the roughness. When plating the surface of the insulating layer, since the electrolytic copper plating by the electrolysis is not performed, the electroless copper plating which is performed by a precipitation reaction is first performed and then the electrolytic copper plating is performed. The electroless copper plating is a method for plating a surface of an insulator and is difficult to make a thickness of a plating film thick and have more deteriorated physical properties than those of the electrolytic copper plating. Therefore, the electroless copper plating is performed and then the electrolytic copper plating is performed using the conductivity, in which the electrolytic copper plating easily forms the thick plating film and have excellent physical properties of the film. Consequently, the electroless copper plating is performed as a preprocessing process for smoothly performing the electrolytic copper plating as draft plating for electrolytic copper plating and thus is difficult to be used as it is and therefore the electrolytic copper plating is additionally performed to be able to supplement the plating performance.

As such, the copper clad formed on the insulating layer is formed to have a thickness of 3 to 10 μm with respect to the overall thickness of the printed circuit board depending on the fine pattern machining degree by the patterning.

Consequently, the copper clad laminate manufactured according to at least one embodiment of the invention has the adhesion (peel strength) about 30% higher than that of the general copper clad laminate by further adding the stress relaxation filler to the insulating layer. Therefore, the copper clad laminate according to at least one embodiment of the invention is widely used as a substrate build-up insulating material and a heat radiating substrate insulating material.

Next, a sample for measuring the peel strength of the copper clad laminate according to at least one embodiment of the invention is manufactured and the peel strength thereof is measured as follows.

### Example 1

### Manufacture of Copper Clad Laminate which is Added with Stress Relaxation Filler

1) Add alumina (Al₂O₃) filler to epoxy resin and melt it in methyl ethyl ketone which is the solvent to produce the first varnish. In this case, the amount of resin in the first varnish is set to be 20 wt % and the amount of alumina filler is set to be 80 wt %.

2) Add the stress relaxation filler to the epoxy resin, along with the alumina filler and melt it in the methyl ethyl ketone (MEK) which is the solvent to produce the second varnish. In this case, the amount of stress relaxation filler is 0.1 wt % with respect to the alumina filler.

3) Form the insulating film by impregnating the inorganic reinforcement material in the first varnish and then inject the second varnish onto the surface of the insulating film by the spray method.

The prepreg is manufactured by drying the varnish by the drier at 80° C. and the prepared copper thin film is formed with roughness.

5) Press the copper clad formed with the roughness to the prepreg. In this case, the size of the sample is set to be 1 cm×1 cm.

6) Stack the copper clad and the insulating film with the applied heat and pressure.

### Comparative Example 1

### Manufacture of Copper Clad Laminate which is not Added with Stress Relaxation Filler

1) Add alumina (Al₂O₃) filler to epoxy resin and melt it in methyl ethyl ketone which is the solvent to produce the varnish. The amount of resin in the varnish is set to be 20 wt/and the amount of alumina filler is set to be 80 wt %.

2) Manufacture the insulating film by impregnating the inorganic reinforcement material into the varnish in the impregnating bath and dry it in the drier at 80° C. to manufacture the prepreg.

3) Form the roughness on the prepared copper thin film.

4) Press the copper clad formed with the roughness to the prepreg. In this case, the size of the sample is set to be 1 cm×1 cm.

The measurement results of the peel strength of the copper clad laminate added with the stress relaxation filler formed by the above processes and the peel strength of the copper clad laminate which is not added with the stress relaxation filler are shown in the following Table 1.

TABLE 1

| | Peel Strength (N/mm) | | | | |
|---|---|---|---|---|---|
| Division | Sample 1 | Sample 2 | Sample 3 | Sample 4 | Average |
| Example | 1.2396 | 1.2041 | 1.2201 | 1.2284 | 1.2231 |
| Comparative | 0.8879 | 0.9379 | 0.9050 | 0.9435 | 0.9186 |
| Example | | | | | |

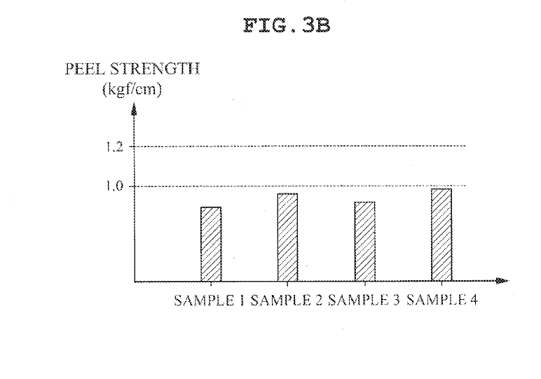

For the accuracy of the experiment, the sample (1 cm×1 cm in size) having the same condition was measured four times. The numerical values of Table 1 are shown by a graph in FIGS. 3A and 3B.

FIG. 3A is a graph illustrating the measurement result of the peel strength of the copper clad laminate added with the stress relaxation filler according to at least one embodiment of the invention, and FIG. 3B is a graph illustrating the measurement result of the peel strength of the general copper clad laminate, which is not added with the stress relaxation filler.

As can be appreciated through Table 1 and FIGS. 3A and 3B, it may be appreciated that since in the case of the copper clad laminate added with the stress relaxation filler, the peel strength is 1.22 N/mm in average, the peel strength is higher than the peel strength of 0.92 N/mm in the case of the copper clad laminate, which is not added with the stress relaxation filler. That is, when the sample having a size of 1 cm×1 cm is pulled up to 45 mm, it may be appreciated that the peel strength (bonding strength) of the copper clad laminate added with the stress relaxation filler is about 30% higher than that of the copper clad laminate which is not added with the stress relaxation filler. This is a result depending on whether the stress relaxation filler is added and has a difference from the effect which is shown when the stress relaxation filler is put in the vicinity of the bonded interface between the insulating layer and the copper clad layer, not in the overall resin Thus, the peel strength effect when the stress relaxation filler is added is the same, but when the stress relaxation filler is put in the vicinity of the bonded interface between the insulating layer and the copper clad layer, the production process is simplified and thus the price competitiveness is increased and the deformation of the existing epoxy matrix is minimized.

Therefore, the stress relaxation filler is added at about 20% of the overall thickness of the insulating layer from the place where the insulating layer and the copper clad layer are broken, that is, the bonded interface between the insulating layer and the copper clad layer, thereby increasing the peel strength of the copper clad laminate and improving the adhesion of the substrate. Consequently, the copper clad laminate according to at least one embodiment formed by the process has the adhesion about 30% higher than that of the general copper clad laminate.

As set forth above, according to at least one embodiment of the invention, it is possible to improve the adhesion by dispersing the stress relaxation filler into the resin, along the inorganic filler.

Further, according to various embodiments of the invention, it is possible to improve the overall adhesion (peel strength) by entirely dispersing the stress relaxation filter into the varnish and more effectively adding the stress relaxation filler in the vicinity of a bonded interface between the insulating layer and the copper clad layer.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A copper clad laminate in which a copper clad is stacked on one surface or both surfaces of an insulating layer, wherein the insulating layer comprises an inorganic filler and a stress relaxation filler.

2. The copper clad laminate according to claim 1, wherein the stress relaxation filler is an elastic material.

3. The copper clad laminate according to claim 1, wherein the stress relaxation filler is added at 20 part per hundred resin with respect to a resin forming the insulating layer.

4. The copper clad laminate according to claim 1, wherein the stress relaxation filler is added into the resin forming the insulating layer at 0.05 wt % or more to 10 wt % or less with respect to the existing inorganic filler.

5. The copper clad laminate according to claim 1, wherein the stress relaxation filler is included in the vicinity of a bonded interface between the insulating layer and the copper clad layer.

6. The copper clad laminate according to claim 5, wherein the stress relaxation filler is distributed in a region adjacent to the bonded interface between the insulating layer and the copper clad layer and is distributed in a thickness region of about 20% with respect to the overall thickness of the insulating layer at the bonded interface between the insulating layer and the copper layer.

7. A method for manufacturing a copper clad laminate, the method comprising:
preparing a first varnish, a second varnish comprising a stress relaxation filler, an inorganic reinforcement material, and a copper clad;
impregnating the first varnish into the inorganic reinforcement material to produce an insulating film;
injecting a second varnish comprising the stress relaxation filler onto the insulating film;
drying the insulating film onto which the second varnish is injected to produce a prepreg (PPG);
forming roughness on the copper clad; and
pressing the copper clad to the prepreg.

8. The method according to claim 7, wherein the stress relaxation filler is an elastic material.

9. The method according to claim 7, wherein the stress relaxation filler is added at 20 part per hundred resin with respect to a resin forming the insulating film.

10. The method according to claim 7, wherein the stress relaxation filler is added into the resin forming the insulating film at 0.05 wt % or more to 10 wt % or less with respect to the existing inorganic filler.

11. The method according to claim 7, wherein the stress relaxation filler is distributed in a region adjacent to a bonded interface between the insulating film and the copper clad layer.

12. A method for manufacturing a copper clad laminate, the method comprising:
preparing a first varnish, a second varnish comprising a stress relaxation filler, an inorganic reinforcement material, and a copper clad;
impregnating the first varnish into the inorganic reinforcement material to produce an insulating film;
injecting a second varnish comprising the stress relaxation filler onto the insulating film;
drying the insulating film onto which the second varnish is injected to produce a prepreg (PPG);
forming roughness on a surface of the prepreg;
performing electroless plating on the prepreg formed with the roughness; and
performing electroplating on the electroless-plated prepreg.

13. The method according to claim 12, wherein the stress relaxation filler is an elastic material.

14. The method according to claim 12, wherein the stress relaxation filler is added at 20 part per hundred resin with respect to a resin forming the insulating layer.

15. The method according to claim 12, wherein the stress relaxation filler is added into the resin forming the insulating film at 0.05 wt % or more to 10 wt % or less with respect to the existing inorganic filler.

16. The method according to claim 12, wherein the stress relaxation filler is distributed in a region adjacent to a bonded interface between the insulating film and the copper clad layer.
